(19) United States
(12) Patent Application Publication
(10) Pub. No.: US 2024/0321569 A1
(43) Pub. Date: Sep. 26, 2024

(54) FORMATION METHOD OF SILICON NITRIDE FILM

(71) Applicant: Dexerials Corporation, Tochigi (JP)

(72) Inventors: Tsukasa MOURI, Tochigi (JP); Etsuji OMURA, Tochigi (JP)

(73) Assignee: Dexerials Corporation, Tochigi (JP)

(21) Appl. No.: 18/736,434

(22) Filed: Jun. 6, 2024

Related U.S. Application Data
(63) Continuation of application No. PCT/JP2021/045119, filed on Dec. 8, 2021.

(51) Int. Cl. H01L 21/02

(52) U.S. Cl. CPC H01L 21/0217; H01L 21/02274

(57) ABSTRACT

A silicon nitride film is formed on the surface of the semiconductor substrate by supplying a raw material gas containing SiH₄, NH₃ and N₂ into a reaction chamber by a plasma-accelerated chemical vapor deposition method, the ratio of the binding energy of the Si—H bond to the binding energy of the N—H bond in the silicon nitride film is defined as the binding energy ratio, and the ratio of the supply flow rate of NH₃ to SiH₄ is defined as the supply flow rate ratio, the supply flow rate ratio is set so that the sum of the concentration of the N—H bond multiplied by the binding energy ratio and the concentration of the Si—H bond is minimized.

### CROSS-REFERENCE TO RELATED APPLICATION

This application is a continuation of the International PCT application serial no. PCT/JP2021/045119, filed on Dec. 8, 2021. The entirety of the above-mentioned patent application is hereby incorporated by reference herein and made a part of this specification.

### TECHNICAL FIELD

The present invention relates to a method for forming a silicon nitride film on a semiconductor substrate, and in particular to a method for forming a plasma silicon nitride film formed by a plasma CVD method.

### BACKGROUND ART

Conventionally, the plasma silicon nitride film (P-SiN) has been used as a thin film for selective diffusion for forming a semiconductor element such as a light receiving element on a semiconductor substrate, and as a protective film for protecting the semiconductor element from oxygen and moisture contained in the air, for example. This P-SiN film is useful in the manufacture of semiconductor devices because it can be formed at a low temperature of, for example, 400° C. or lower, and has excellent step coating properties and stain resistance, and can be used as an antireflection film for light receiving elements.

Generally, a raw material gas containing SiH₄, NH₃ and N₂ is supplied to a reaction chamber in which a semiconductor substrate is installed, and the raw material gas is reacted in a plasma excited state by applying a high-frequency voltage, thereby P-SiN film is formed on the semiconductor substrate. In addition to the Si—N bond, the Si—H bond and the N—H bond derived from the raw material gas remain in the formed P-SiN film. These Si—H bonds and N—H bonds tend to increase as the formation temperature of the P-SiN film decreases.

For example, in Patent Document #1, in order to stabilize the interface between the surface of the semiconductor device and the P-SiN film, the concentration (number) of Si—H bonds in the P-SiN film is set to 1×10²²/cm³ or more, thereby the chemical activity is high. An energetically unstable dangling bond, a semi-stable hydrogen terminator, etc. on the surface of a semiconductor device are stimulated to transit to an energetically more stable state by reacting with a P-SiN film in a state of high chemical activity, thereby the generation of interface levels is suppressed.

When heat energy is applied by, for example, heat treatment after forming the P-SiN film, the Si—H bond and the N—H bond in the P-SiN film are broken, H (hydrogen) is separated, and the separated hydrogen causes later, peeling of the P-SiN film from the substrate. In particular, as in Patent Document 1, when the concentration of Si—H bond is high and a large amount of hydrogen is separated, peeling is likely to occur. When this peeling occurs at the interface with the surface of the semiconductor device which is the base of the P-SiN film, the interface state increases and the characteristics of the semiconductor device deteriorate. Further, when the P-SiN film is used as an antireflection film, the antireflection function deteriorates due to peeling from the substrate.

In order to prevent peeling at the interface between the substrate and the P-SiN film, for example, as in Patent Document #2, a technique for forming a plasma silicon oxide film (P—SiO film) on the substrate and then forming a P-SiN film is known. Further, in order to prevent the P-SiN film from peeling off, the hydrogen content in the P-SiN film is reduced by controlling the decomposition amount while measuring the decomposition amount of NH3 in the reaction chamber as in Patent Document #3.

### PRIOR ART DOCUMENTS

### Patent Documents

Patent Document #1: Japanese Patent Publication No. 5186776.
Patent Document #2: Japanese Patent Laid-Open Publication No. H4-184932.
Patent Document #3: Japanese Patent Publication No. 3045945.

### SUMMARY OF THE INVENTION

### Problems to be Solved by the Invention

However, sandwiching the P—SiO film between the substrate and the P-SiN film as in Patent Document 2 is not preferable because the manufacturing process becomes complicated and the manufacturing cost increases. Further, as in Patent Document 3, changing the flow rate of NH₃ or the like in order to control the decomposition amount of NH₃ during the formation of the P-SiN film constantly changes the formation conditions of the P-SiN film to be formed. As a result, the film quality is not stable, which may cause variations in the characteristics of the semiconductor element and deterioration of the antireflection function.

Therefore, there was a need for a method of forming of P-SiN such that the hydrogen content in the film can be reduced so as to prevent peeling from the substrate, that is, the concentration of Si—H bond and NH bond in the film can be reduced. Present invention provides a method for forming a silicon nitride film capable of reducing the hydrogen content in the film and preventing peeling from the substrate.

### Means to Solve the Problems

The present invention presents a method for forming a silicon nitride film by supplying a raw material gas containing SiH₄, NH₃ and N₂ into a reaction chamber in which a semiconductor substrate is installed and forming a silicon nitride film on a surface of the semiconductor substrate by a plasma accelerated chemical vapor deposition method, comprising: a ratio of a binding energy of a Si—H bond to a binding energy of a N—H bond contained in the silicon nitride film is defined as a binding energy ratio, and a ratio of a supply flow rate of NH₃ to a supply flow rate of SiH₄ is defined as a supply flow rate ratio, a supply flow rate ratio setting step of setting the supply flow rate ratio so that a sum of a concentration of the N—H bond multiplied by the binding energy ratio in the silicon nitride film and a concentration of the Si—H bond is minimized, and a silicon nitride film forming step of supplying the SiH₄ and the NH₃ at the supply flow rate ratio set in the supply flow rate ratio setting step to form the silicon nitride film.

According to the above configuration, the silicon nitride film formed on the underlying semiconductor substrate contains Si—N bonds, Si—H bonds, and N—H bonds. The concentration of Si—H bond and the concentration of N—H bond in this film vary depending on the supply flow ratio of SiH₄ and NH₃ at the time of forming the silicon nitride film. For example, when the supply flow rate of NH₃ is larger than the supply flow rate of SiH₄, the number of N—H bonds increases and the number of Si—H bonds decreases.

On the contrary, when the supply flow rate of NH₃ is smaller than the supply flow rate of SiH₄, the N—H bond is reduced and the Si—H bond is increased. The N—H bond in the silicon nitride film has a larger binding energy than the Si—H bond, and the ratio of the Si—H binding energy to the binding energy of the N—H binding energy is defined as the binding energy ratio. This binding energy ratio corresponds to the relative breaking probability of the N—H bond with respect to the breaking probability of the Si—H bond in the silicon nitride film. Then, the supply flow rate ratio of SiH₄ and NH₃ is set so that the sum of the concentration of the N—H bond multiplied by the binding energy ratio and the concentration of the Si—H bond in the silicon nitride film is minimized, and the supply flow rate ratio is used in forming a silicon nitride film. As a result, the concentration of H (hydrogen) converted to the equivalent of Si—H bond in the silicon nitride film can be minimized, so that the amount of H (hydrogen) separated can be minimized, and can be prevented from peeling off.

The method for forming the silicon nitride film according to the another aspect of the present invention is the method for forming a silicon nitride, wherein the supply flow ratio is determined based on the binding energy ratio calculated by a Fourier transform infrared spectroscopy in the supply flow ratio setting step, and a relationship between the concentration of the Si—H bond and the N—H bond calculated by the Fourier transform infrared spectroscopy and the supply flow rate ratio.

According to the above configuration, for the silicon nitride film formed in advance, the binding energy ratio is calculated in the supply flow rate ratio setting step, and the relationship between the supply flow rate ratio, the concentration of Si—H bond and the NH bond in the silicon nitride film are calculated.

Then, based on the relationship between the set supply flow rate ratio and the bond concentrations and the binding energy ratio in the silicon nitride film. The supply flow ratio is set so that the concentration of H (hydrogen) converted to the equivalent of Si—H bond in the silicon nitride film is minimized. Therefore, an appropriate supply flow rate ratio of SiH₄ and NH₃ can be set according to the reaction chamber, and peeling of the formed silicon nitride film from the substrate can be prevented.

### Advantages of the Invention

According to the method of forming silicon nitride film of the present invention, the hydrogen content in the film can be reduced to prevent exfoliation from the substrate.

### BRIEF DESCRIPTION OF THE DRAWINGS

FIG. 1 is a cross-sectional view showing an example in which a P-SiN film is used as a thin film for selective diffusion;

FIG. 2 is an explanatory diagram of a forming condition setting step and a nitride film forming step;

FIG. 3 is an example of absorption spectrum measurement by FTIR of the P-SiN film;

FIG. 4 is a cross-sectional view showing an example of peeling of the P-SiN film;

FIG. 5 is an explanatory diagram of the supply flow rate ratio setting process; and

FIG. 6 is a graph showing the relationship between the supply flow rate ratio FR and the concentration C1 of the Si—H bond and the concentration C2 of the N—H bond.

### DESCRIPTION OF EMBODIMENTS

Best mode for implementing the present invention will now be explained on the basis of embodiments.

### Embodiment

First, a silicon nitride film (P-SiN film) formed by a plasma-accelerated chemical vapor deposition method (plasma CVD method) will be described.

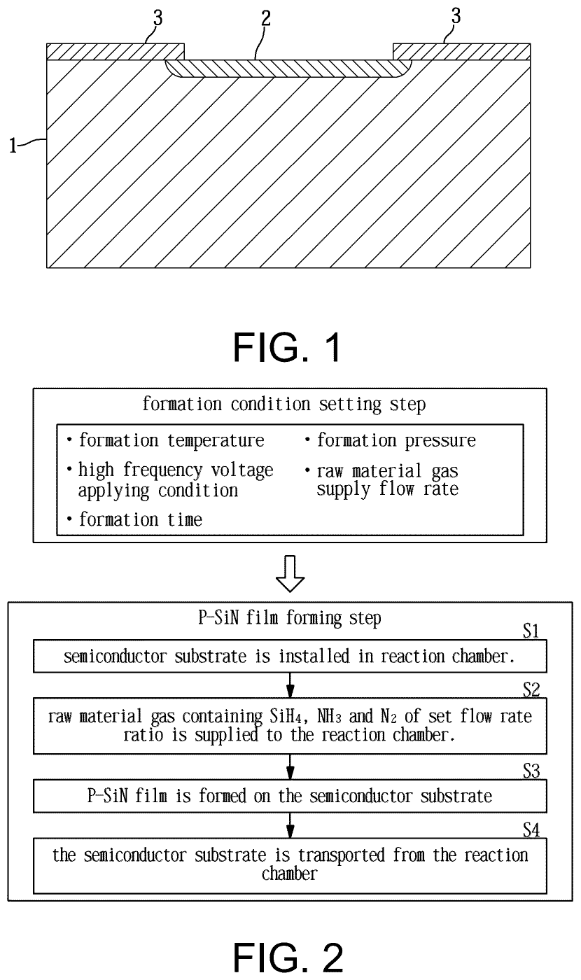

The P-SiN film can be formed thicker, for example, up to about 1 m at a low temperature of 400° C. or lower, as compared with the silicon nitride film (LP-SiN film) formed by the conventional reduced pressure CVD method, and is used in the manufacture of semiconductor devices. Further, the P-SiN film is excellent in step covering property, moisture resistance and stain resistance like the LP-SiN film. Therefore, as shown in FIG. 1, the P-SiN film is used as a mask layer 3 for selectively forming the impurity diffusion layer 2 on the semiconductor substrate 1, for example. Further, the P-SiN film may also be used as a protective film for covering the surface of the semiconductor element formed on the semiconductor substrate 1, and when the semiconductor element is a light receiving element, it may also be used as a antireflection that reduces the reflection of incident light.

Next, a method for forming the P-SiN film will be described.

As shown in FIG. 2, the P-SiN film is formed by setting the formation conditions in the reaction chamber in advance in the formation condition setting step and according to the formation conditions in the silicon nitride film forming step Sj (j=1, 2, . . . ) in the figure represents steps. The formation conditions to be set include a plurality of parameters that determine the film quality, film thickness, etc. of the P-SiN film, such as formation temperature, formation pressure, high frequency application conditions, raw material gas supply flow rate, and formation time.

In the silicon nitride film forming step, the semiconductor substrate 1 that is the base of the P-SiN film formed in Si is installed in the reaction chamber. Then, in S2, for example, after air is discharged from the reaction chamber, according to the formation conditions, a raw material gas containing SiH₄ (silane), NH₃ (ammonia) and N₂ (nitrogen) is supplied to the reaction chamber. For example, SiH₄ is supplied at 5 sccm, NH₃ at 10 sccm, and N₂ at 60 sccm.

Next, in S3, the P-SiN film is formed on the semiconductor substrate 1 by reacting the raw material gas in a plasma excited state by applying a high frequency voltage while the raw material gas flow is stable. For example, a high frequency of 75 W and 13.56 MHz is applied, but the present invention is not limited to this. Finally, in S4, the semiconductor substrate 1 on which the P-SiN film is formed is transported to the outside from the reaction chamber returned to the atmospheric pressure after the raw material gas is exhausted. By forming the P-SiN film on another semiconductor substrate under the same formation conditions, variations in film quality and film thickness between the semiconductor substrates can be suppressed.

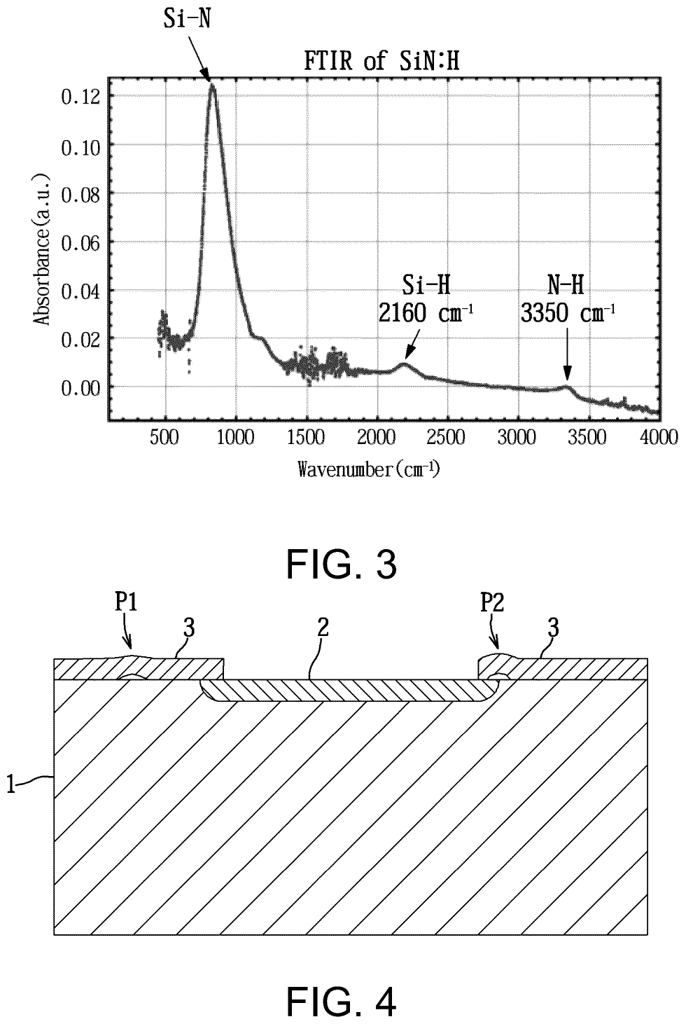

The formed P-SiN film contains not only Si—N bonds but also Si—H bonds and N—H bonds derived from the raw material gas. The binding energy of the Si—H bond and the binding energy of the N—H bond in the P-SiN film are calculated based on, for example, as shown in FIG. 3, in the absorption spectrum measurement of the P-SiN film by Fourier transform infrared spectroscopy (FTIR). It is calculated based on the wave number corresponding to the Si—H bond and the wave number corresponding to the N—H bond. Since a small wave number corresponds to a long wavelength, that is, a small energy, the binding energy of the Si—H bond is smaller than the binding energy of the N—H bond in the P-SiN film. The binding energy basically does not fluctuate depending on the formation conditions.

Further, the concentration of Si—H bond and the concentration of N—H bond in the P-SiN film are calculated based on the heights of the absorption peaks corresponding to the Si—H bond and the N—H bond in the absorption spectrum measurement of the P-SiN film by FTIR. The higher the formation temperature of the P-SiN film, the lower the concentration of Si—H bond and the concentration of N—H bond in this film, but usually the concentration of N—H bond is higher than the concentration of Si—H bond.

When the heat treatment is performed after the formation of the P-SiN film, a part of the Si—H bond and a part of the N—H bond are cut by receiving heat energy, and H (hydrogen) is separated. Then, for example, as shown in FIG. 4, the separated hydrogen becomes a hydrogen molecule at the interface between the substrate (semiconductor substrate 1) and the P-SiN film (mask layer 3), and the film may be peeled off from the substrate as shown in the regions P1 and P2, for example. In order to prevent this peeling, it is effective to reduce the hydrogen content in the P-SiN film, that is, to reduce the concentration of Si—H bond and the concentration of N—H bond.

It is difficult to raise the formation temperature in order to reduce the concentration of Si—H bond and the concentration of N—H bond because it may greatly affect the characteristics of the semiconductor device. Further, the concentration of the Si—H bond and the concentration of the N—H bond vary depending on the formation conditions other than the formation temperature of the P-SiN film. Therefore, in the formation condition setting step, the formation conditions that can reduce the concentration of Si—H bond and the concentration of N—H bond in the P-SiN film are set.

For example, in setting the supply flow rate of the raw material gas included in the formation condition setting step, the concentration of the N—H bond can be reduced by reducing the supply flow rate of NH₃. In this setting, if the ratio of the supply flow rate of NH₃ to the supply flow rate of SiH₄ is the supply flow rate ratio FR (supply flow rate ratio FR=NH₃ supply flow rate/SiH₄ supply flow rate), above setting corresponds to the ratio setting process that set the supply flow rate ratio FR to be small. It is also possible to reduce the supply flow rate ratio FR by changing the supply flow rate of SiH₄ or changing the supply flow rates of SiH₄ and NH₃ respectively. The supply flow rates of SiH₄ and NH₃ are appropriately set according to the volume of the reaction chamber and the like, and are set in the range of, for example, 30 sccm or less, respectively.

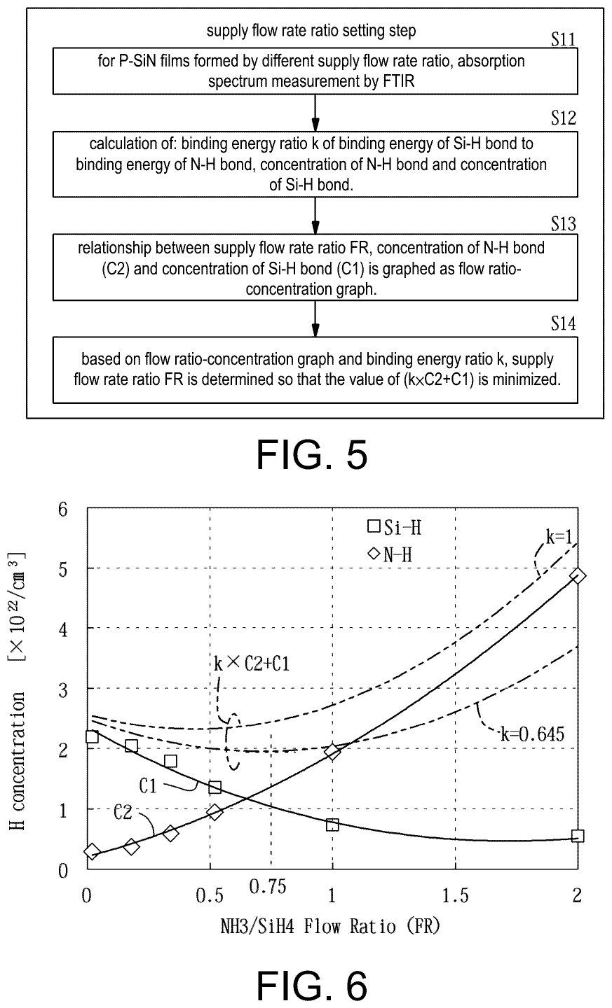

In order to set an appropriate supply flow rate ratio FR in this supply flow rate ratio setting step, for example, as shown in FIG. 5, in S11, absorption spectrum measurement by FTIR is performed for P-SiN films formed with different supply flow rate ratios FR. Then, in S12, for each P-SiN film formed with different supply flow ratios FR, the concentration of Si—H bond and the concentration of N—H bond in this film are calculated, respectively. The binding energy ratio k, which is the ratio of the binding energy of the N—H bond to the biding energy of Si—H is calculated.

Next, in S13, the relationship between the supply flow rate ratio FR, the calculated concentration of Si—H bond, and the concentration of N—H bond is graphed as shown in FIG. 6, and the concentration curve showing the concentration C1 of Si—H bond with respect to the supply flow rate ratio FR is calculated, the concentration curve showing the concentration C2 of the N—H bond with respect to the supply flow rate ratio FR are calculated. Finally, in S14 of FIG. 5, the sum of the concentration of the N—H bond (k×C2) multiplied by the calculated binding energy ratio k and the concentration C1 of the Si—H bond is calculated, and sets the supply flow ratio FR that minimizes the sum (k×C2+C1).

According to FIG. 6, when the supply flow rate ratio FR is reduced from 2, the decrease in the concentration C2 of the N—H bond is larger than the increase in the concentration C1 of the Si—H bond, the H (hydrogen) content in the P-SiN film can be reduced. On the other hand, since the binding energy of the Si—H bond is smaller than the binding energy of the N—H bond in the P-SiN film, the Si—H bond is more easily cleaved than the N—H bond, and when the supply flow ratio FR is reduced excessively, the amount of hydrogen separated may increase.

Here, the calculated binding energy ratio k can be regarded as the relative cutting probability of the N—H bond with respect to the cutting probability of the Si—H bond in the P-SiN film by heat treatment. By multiplying this binding energy ratio k as a coefficient of the concentration C2 of the N—H bond, the concentration of the N—H bond that is relatively difficult to be cleaved is converted so as to correspond to the Si—H bond, and the concentration of H (hydrogen) that is easily separated in the film is calculated, and the supply flow ratio FR that minimizes this concentration is set.

When the value of the binding energy ratio k calculated from the absorption spectrum measurement by FTIR is, for example, 0.645, the supply flow ratio FR is 0.75. Since the supply flow rate ratio FR is set so as to minimize the H (hydrogen) concentration that is easily separated due to the difference in binding energy, not the sum of the concentrations C1 and C2 (k=1), the supply flow rate ratio FR is reduced. Thus, the supply flow rate cannot be reduced excessively, and the P-SiN film formed by the supply flow rate ratio FR is less likely to peel off.

The action and effect of the above P-SiN film forming method will be described. The P-SiN film formed on the semiconductor substrate on which the underlying semiconductor element is formed contains Si—N bonds, Si—H bonds, and N—H bonds. The concentration of Si—H bond and the concentration of N—H bond in the P-SiN film vary depending on the supply flow rate ratio FR of SiH₄ and NH₃ at the time of forming the P-SiN film. Since the binding energy of the N—H bond and the binding energy of the Si—H bond in the P-SiN film are different, the ratio of the Si—H binding energy to the N—H binding energy is defined as the binding energy ratio k. This binding energy ratio k corresponds to the relative breaking probability of the N—H bond with respect to the breaking probability of the Si—H bond in the P-SiN film. Then, in order that, in the supply flow ratio setting step, the sum of the concentration C1 of the Si—H bond and the concentration C2 of the N—H bond multiplied by the binding energy ratio k in the P-SiN film is minimized, the supply flow rate ratio FR of SiH₄ and NH₃ is set, and the P-SiN film is formed by this supply flow rate ratio FR in the silicon nitride film forming step. As a result, the concentration of H (hydrogen) converted to the equivalent of Si—H bond in the P-SiN film can be minimized, so that the amount of H (hydrogen) separated can be minimized, and it is possible to prevent the P-SiN film from peeling off from the base.

In the supply flow ratio setting step, the binding energy ratio is calculated based on the absorption spectrum measured by FTIR for the P-SiN film formed in advance, and the relationship between the supply flow ratio FR of NH₃ to SiH₄ and the concentration of Si—H bond and the concentration of N—H bond are determined. Based on the relationship between the set supply flow ratio FR and the binding concentration of H (hydrogen) in the P-SiN film, and the binding energy ratio, the value of the supply flow ratio FR is set so that the concentration of H (hydrogen) converted to the equivalent of Si—H bond in the P-SiN film is minimized. Therefore, it is possible to set an appropriate value of the supply flow rate ratio FR of SiH₄ and NH₃ according to the reaction chamber based on the formed P-SiN film, and to prevent the formed silicon nitride film from peeling from the substrate.

1. A method for forming a silicon nitride film by supplying a raw material gas containing SiH₄, NH₃ and N₂ into a reaction chamber in which a semiconductor substrate is installed and forming a silicon nitride film on a surface of the semiconductor substrate by a plasma accelerated chemical vapor deposition method, comprising:
a ratio of a binding energy of a Si—H bond to a binding energy of a N—H bond contained in the silicon nitride film is defined as a binding energy ratio, and a ratio of a supply flow rate of NH₃ to a supply flow rate of SiH₄ is defined as a supply flow rate ratio, a supply flow rate ratio setting step of setting the supply flow rate ratio so that a sum of a concentration of the N—H bond multiplied by the binding energy ratio in the silicon nitride film and a concentration of the Si—H bond is minimized, and
a silicon nitride film forming step of supplying the SiH₄ and the NH₃ at the supply flow rate ratio set in the supply flow rate ratio setting step to form the silicon nitride film.

2. The method for forming a silicon nitride film according to claim 1, wherein the supply flow ratio is determined based on the binding energy ratio calculated by a Fourier transform infrared spectroscopy in the supply flow ratio setting step, and a relationship between the concentration of the Si—H bond and the N—H bond calculated by the Fourier transform infrared spectroscopy and the supply flow rate ratio.
